(19) United States
(12) Patent Application Publication
(10) Pub. No.: US 2025/0105134 A1
(43) Pub. Date: Mar. 27, 2025

(54) Buffer and Inverter Transistors Embedded in Interconnect Metal Layers

(71) Applicant: Apple Inc., Cupertino, CA (US)

(72) Inventors: Xin Miao, Saratoga, CA (US); Saurabh P. Sinha, Austin, TX (US)

(21) Appl. No.: 18/883,389

(22) Filed: Sep. 12, 2024

Related U.S. Application Data
(60) Provisional application No. 63/585,402, filed on Sep. 26, 2023.

(51) Int. Cl. H01L 23/50; H01L 23/535; H01L 25/11; H01L 29/40; H01L 29/423

(52) U.S. Cl. CPC H01L 23/50; H01L 23/535; H01L 25/112; H10D 64/112; H10D 64/118; H10D 64/518

(57) ABSTRACT

Integrated circuit devices with buffer transistors or inverter transistors formed between topside BEOL (back end of line) metal layers are described. The buffer or inverter transistors include active regions and source/drains that can be formed in the spaces between topside metal layers. In certain instances, the transistors are formed in between metal layers furthest away from substrate. The transistors connect to routing either above or below the transistors to buffer and/or invert signals passing through the routing. For instance, the transistors may include active regions positioned between power and ground routings and connect to signal routing between the power and ground routings to boost and/or to invert the signal propagating along the signal routing. In various instances, the active regions of the transistors are formed by thin channel materials.

### PRIORITY CLAIM

The present application claims priority to U.S. Provisional App. No. 63/585,402, entitled “Buffer Transistors Embedded in Interconnect Metal Layers,” filed Sep. 26, 2023, the disclosure of which is incorporated by reference herein in its entirety.

### BACKGROUND

### Technical Field

Embodiments described herein relate to signal routing for semiconductor devices. More particularly, embodiments described herein relate to implementation of buffer or inverter transistors in interconnect layers for buffering signals.

### Description of the Related Art

Large scale integrations of integrated circuits (such as very-large scale integrations (VLSIs)) may have signals that globally travel between numerous circuits or blocks of circuits. In some instances, these signals may travel over long distances across numerous circuits or blocks of circuits. In such instances, the signals may need to be boosted (e.g., amplified or buffered) at one or more points along their paths to maintain signal strength and acceptable signal-to-noise ratios for the signals. In current implementations, buffering or inverting is typically implemented by the placement of buffer or inverter circuits in transistor regions of the devices (e.g., at the silicon/CMOS level of the devices). Placing the buffer or inverter circuits in the transistor regions, however, requires signal travel along vias between the transistor regions and the global signal routes layers that are typically in topside metal layers of the devices.

Having the buffer or inverter circuits in the transistor regions takes up valuable silicon footprint in the transistor regions and still generates longer travel paths by the signals going up/down between the transistor regions and the topside metal layers. Additionally, the buffer or inverter circuits and their associated vias to the topside metal layers create path blockages that need to be accommodated in the design of the devices. For instance, complex or undesired pathways may be needed to route signals around path blockages caused by buffer or inverter circuits and their associated vias. Thus, there are both electrical (e.g., high resistance over long travel paths) and mechanical (e.g., footprint and path blockage) issues associated with buffer or inverter circuits being located in transistor regions.

### BRIEF DESCRIPTION OF THE DRAWINGS

Features and advantages of the methods and apparatus of the embodiments described in this disclosure will be more fully appreciated by reference to the following detailed description of presently preferred but nonetheless illustrative embodiments in accordance with the embodiments described in this disclosure when taken in conjunction with the accompanying drawings in which:

FIG. 1 depicts a top view representation of a contemplated device with buffer transistors in between topside metal layers, according to some embodiments.

FIG. 2 is a cross-sectional side-view representation of a device showing a buffer transistor along line 2-2 in FIG. 1, according to some embodiments.

FIG. 3 is a cross-sectional side-view representation of a device showing a buffer transistor along line 3-3 in FIG. 1, according to some embodiments.

FIG. 4 depicts a three-dimensional perspective view representation of a buffer transistor, according to some embodiments.

FIG. 5 depicts a schematic view representation of a buffer transistor, according to some embodiments.

FIG. 6 depicts a three-dimensional perspective view representation of another buffer transistor, according to some embodiments.

FIG. 7 depicts a schematic view representation of another buffer transistor, according to some embodiments.

FIG. 8 depicts a topside plan view representation of a contemplated device showing various layouts of buffer transistors, according to some embodiments.

FIG. 9 is a block diagram of one embodiment of an example system.

Although the embodiments disclosed herein are susceptible to various modifications and alternative forms, specific embodiments are shown by way of example in the drawings and are described herein in detail. It should be understood, however, that drawings and detailed description thereto are not intended to limit the scope of the claims to the particular forms disclosed. On the contrary, this application is intended to cover all modifications, equivalents and alternatives falling within the spirit and scope of the disclosure of the present application as defined by the appended claims.

### DETAILED DESCRIPTION OF EMBODIMENTS

The present disclosure is directed to the implementation of transistors (such as buffer transistors) in between metal layers above a transistor region (e.g., topside metal layers) of integrated circuit devices. In various embodiments, these topside metal layers may be referred to as BEOL (“back end of line”) metal layers. The topside metal layers may provide routing (e.g., paths) for control signals and/or power signals. Many current designs of cells provide connections and routing for power or signals to transistors or other structures in areas above the transistors. For example, the connections and routing for power or signals may be provided in topside layers of the device. As used herein, the term “topside” refers to areas in a device that are vertically above an active layer of the device (e.g., above a transistor region of the device when viewed in a typical cross-sectional view). For example, topside may refer to components such as contacts or layers that are above a transistor region in a vertical dimension, as depicted in the figures and described herein. In some instances, the term “frontside” may be used interchangeably with the term “topside”.

As used herein, the term “routing” refers to any combination of metal vias, metal wires, metal traces, etc. that provide a path/route between two structures. Additional embodiments may be contemplated where the metal in “routing” is replaced with an alternative conductive material. For instance, the metal in “routing” may be replaced with a superconductor material, a semiconductor material, or a non-metal conductor.

As indicated above, placing buffer or inverter transistors in transistor regions of integrated circuit devices in large scale integrations may cause electrical (e.g., high resistance) and mechanical (e.g., footprint/area utilization and path blockage) issues. The present disclosure recognizes that these issues may be alleviated by placing buffer or inverter transistors in locations between topside routing layers (e.g., topside metal routing layers) instead of in the transistor regions of the integrated circuit devices. Placing the buffer or inverter transistors in these locations allows connections between the buffer or inverter transistors and their associated signal routes to be made over small distances. For example, the buffer or inverter transistors may be coupled to signal routes in topside metal layers directly above or below the buffer or inverter transistors. These shorter connection distances reduce resistances in the connections between the buffer or inverter transistors and signal routes, which improves electrical properties for the transmission of the signals. In some instances, the number of buffer or inverter transistors necessary for global transmission of signals across a device may be less by implementing these shorter connection pathways. Reducing the number of buffer or inverter transistors may increase flexibility in the design or manufacturing of these devices.

Moving the buffer or inverter transistors out of the transistor regions of the devices by placing the transistors in between topside metal layers opens up footprint in the transistor regions. The opened up footprint may be utilized, for example, to increase the number of other types of transistors or circuit elements, allowing for more complex or powerful devices. Additionally, moving the buffer or inverter transistors out of the transistor regions of the devices eliminates potential blockages by the transistors. Opening up the footprint and removing blockages may allow more flexibility in the design or manufacturing of integrated circuit devices. For instance, the design of integrated circuits may include more optimized routing strategies for signals in the devices with the opening up of the footprint and removal of blockages. Manufacturing may also be more efficient in certain instances with optimized design strategies.

Certain embodiments disclosed herein have three broad elements: 1) a transistor region; 2) first and second metal layers in topside metal layers above the transistor region where one or more of the metal layers includes signal routing, power supply routing, and ground supply routing, and 3) a transistor circuit positioned between the first and second metal layers. In various embodiments, the transistor circuit is a buffer transistor or inverter transistor that includes an active region, a gate, a signal input coupled to the gate a portion of the signal routing, a voltage supply input coupled to the power supply routing, a ground supply input coupled to the ground supply routing, and a signal output coupled to another portion of the signal routing. In certain embodiments, the signal routing, power supply routing, and ground supply routing are located in the same topside metal layer (e.g., either the first or the second metal layer). In some contemplated embodiments, the transistor circuit is a two-stage or a one-stage inverter circuit where the active region includes a p-type active region and an n-type active region.

Various illustrations of embodiments with these broad elements are now described in the present disclosure. It should be noted that the illustrated embodiments of the present disclosure depict design templates for devices with buffer transistors positioned in between topside metal layers. A person skilled in the art would recognize that the illustrated embodiments in the present disclosure may also be design templates for inverter transistors or combinations of buffer and inverter transistors positioned in between topside metal layers. Accordingly, the design templates depicted in the present disclosure provide basic building blocks from which many different types of routing schemes and logic functions (such as NAND and NOR) for devices may be constructed based on connection schemes to the transistors in the design templates. Additional embodiments may be contemplated that use more metal tracks in either the first metal layer or the second metal layer along with variations in active region sizes and/or widths.

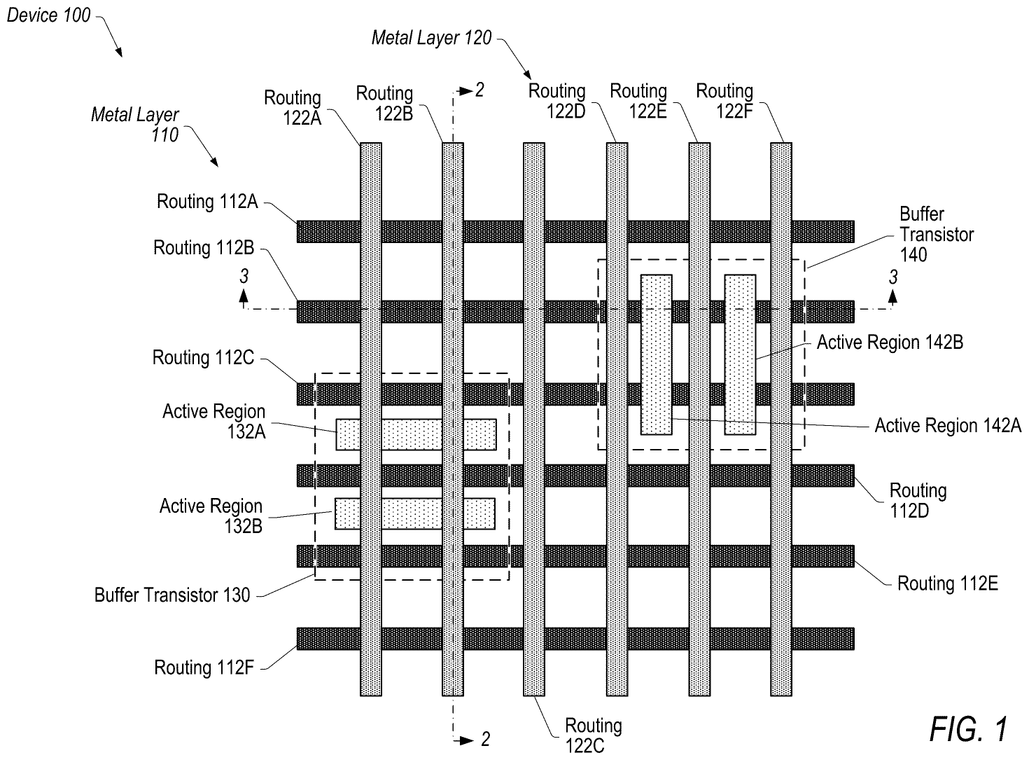

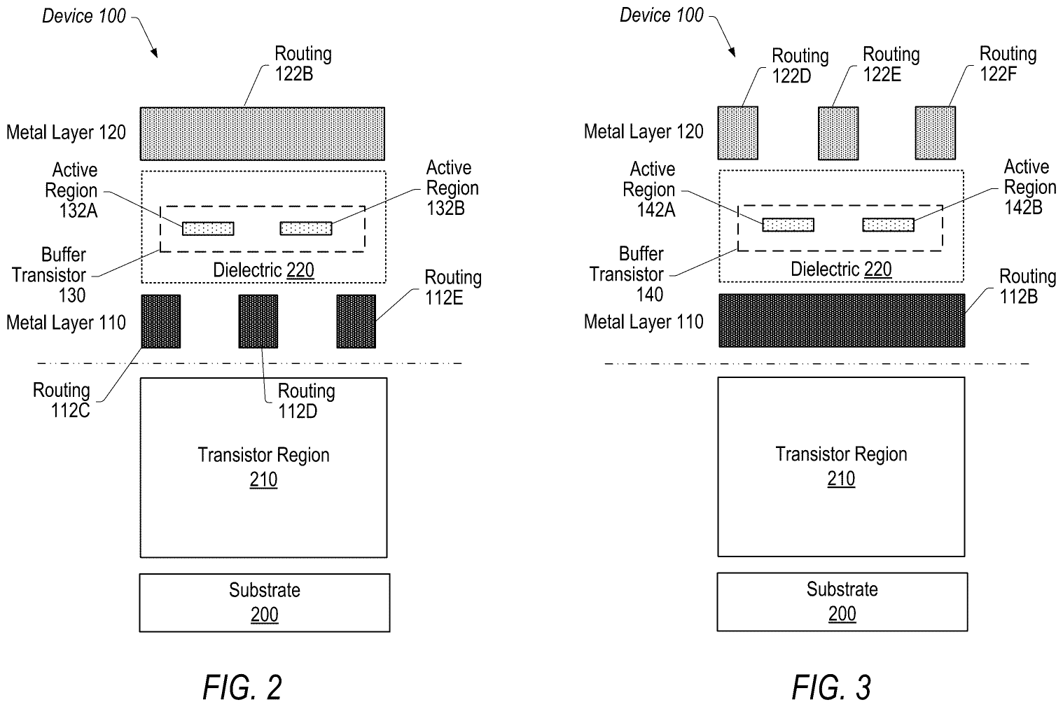

FIG. 1 depicts a top view representation of a contemplated device with buffer transistors in between topside metal layers, according to some embodiments. In the illustrated embodiment, two topside metal layers 110 and 120 for device 100 are shown. Topside metal layers 110 and 120 may be, for example, BEOL metal layers vertically above a transistor region of device 100. In certain embodiments, metal layer 110 is the metal layer that is vertically closer to the transistor region of device 100 (e.g., metal layer 110 is the lower metal layer and metal layer 120 is the top metal layer such as shown in FIGS. 2 and 3).

In various embodiments, metal layer 110 includes routings 112A-F and metal layer 120 includes routings 122A-F. As metal layer 110 and metal layer 120 are neighboring metal layers in the topside metal layers, routings 112A-F and routings 122A-F may run perpendicular to each other, as shown in FIG. 3. Routings 112A-F and routings 122A-F may include signal routing, power supply routing, or ground supply routing. In certain embodiments, one or more of the routings 112 and routings 122 are global routings. Global routings may be, for example, routes that carry signals over long distances and try to avoid diversions in their pathways when passing above transistor regions to which they are not connected.

In certain embodiments, device 100 includes one or more buffer transistors positioned in the space vertically between metal layer 110 and metal layer 120. In the illustrated embodiment, device 100 includes buffer transistor 130 and buffer transistor 140. The dashed lines represent the horizontal areas taken up by buffer transistor 130 and buffer transistor 140. Buffer transistor 130 includes active regions 132 that are positioned in parallel to routings 112 and perpendicular to routings 122. Buffer transistor 140 includes active regions 142 that are positioned in parallel to routings 122 and perpendicular to routings 112. Active regions 132 may cross under routings 122 while active regions 142 cross over routings 112. In various embodiments, active region 132A and active region 132B are complementary active regions (e.g., one is a PMOS active region and one is an NMOS active region). Active region 142A and active region 142B may similarly be complementary active regions.

FIG. 2 is a cross-sectional side-view representation of device 100 showing buffer transistor 130 along line 2-2 in FIG. 1, according to some embodiments. Note that only the portion of device 100 that includes buffer transistor 130 along line 2-2 is shown in FIG. 2. Additionally, the elements in device 100 (such as, but not limited to, substrate 200, transistor region 210, and dielectric 220) along with their dimensions and spacing relative to each other are shown representatively for illustrative purposes. In the illustrated embodiment, device 100 includes substrate 200 with transistor region 210 above the substrate.

In various embodiments, metal layer 110 and metal layer 120 (e.g., the topside/BEOL metal layers) are positioned above transistor region 210. In certain embodiments, metal layer 110 and metal layer 120 are higher metal layers. For instance, metal layer 110 and metal layer 120 may be metal layers that are vertically further away from transistor region 210 than other metal layers (e.g., there are additional metal layers between transistor region 210 and metal layer 110). Metal layer 110 and metal layer 120 may, however, be any pair of adjacent (e.g., vertically neighboring) metal layers positioned above transistor region 210. For instance, embodiments may be contemplated where metal layer 110 and metal layer 120 are the two metal layers vertically closest to transistor region 210.

In certain embodiments, a layer of dielectric 220 is positioned between metal layer 110 and metal layer 120. Dielectric 220 may include any suitable dielectric material for providing electrical insulation and mechanical support between metal layer 110 and metal layer 120. For instance, dielectric 220 may include silicon oxide. Buffer transistor 130, including active regions 132A/132B, may be formed between metal layer 110 and metal layer 120 and surrounded, at least partially, by dielectric 220. In various embodiments, as shown in FIG. 2, active regions 132A, 132B and routings 112C-E are in parallel and extend into/out of the page while routing 122B runs horizontally along the page.

FIG. 3 is a cross-sectional side-view representation of device 100 showing buffer transistor 140 along line 3-3 in FIG. 1, according to some embodiments. Note that only the portion of device 100 that includes buffer transistor 140 along line 3-3 is shown in FIG. 3. Additionally, as with FIG. 2, the elements in device 100 (such as, but not limited to, substrate 200, transistor region 210, and dielectric 220) along with their dimensions and spacing relative to each other are shown representatively for illustrative purposes.

In various embodiments, buffer transistor 140, including active regions 142A/142B, is formed between metal layer 110 and metal layer 120 and surrounded, at least partially, by dielectric 220. In some embodiments, as shown in FIG. 3, active regions 142A, 142B and routings 122D-F are in parallel and extend into/out of the page while routing 112B runs horizontally along the page. As shown in FIGS. 2 and 3, buffer transistors (e.g., buffer transistor 130 or buffer transistor 140) may be formed in the vertical space between two adjacent metal layers (e.g., metal layer 110 and metal layer 120) that are above transistor region 210 (e.g., in topside of the transistor region) of device 100.

In certain embodiments, active regions 132 of buffer transistor 130 and active regions 142 of buffer transistor 140 are active regions made of thin channel materials. For example, the channel materials may be on the order of tens or fewer atomic layers. Thin channel materials may include materials such as, but not limited to, 2D (two-dimensional) materials, CNTs (carbon nano-tubes), and oxide semiconductors (for example, indium gallium zinc oxide and tungsten-doped indium oxide. Examples of 2D materials include, but are not limited to, graphene, silicene, BNNS (boron nitride nanosheets), TMDCs (transition-metal dichalcogenides), phosphorene, and metal oxide nanosheets. Utilizing these types of materials may allow similar active region characteristics to silicon to be achieved in a few layers that can be positioned between existing topside metal layers in a device layout. Buffer transistors with these types of active regions and positioned between topside metal layers, as described herein, may be implemented in various designs of devices with the buffer transistors placed at various locations in devices (such as device 100) to provide buffering for signals propagating across the devices.

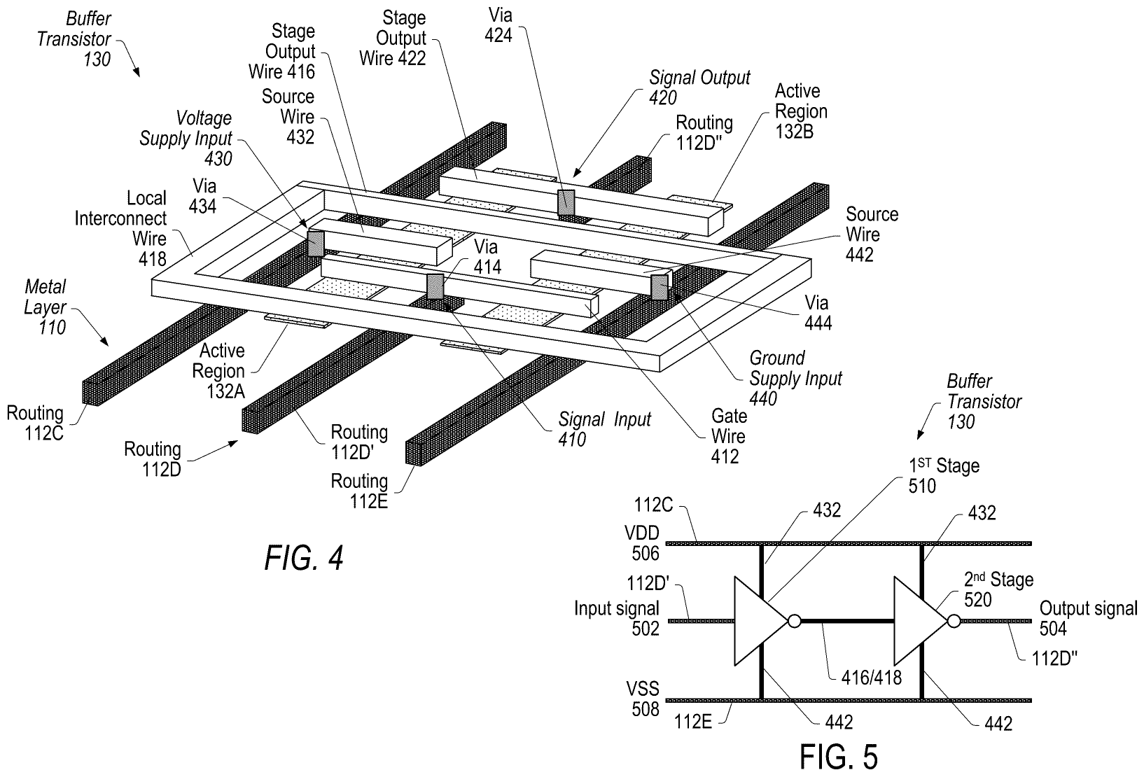

FIGS. 4-7 depict representations of contemplated embodiments for designs of buffer transistors that may be implemented in the space between topside metal layers, as described herein. FIG. 4 depicts a three-dimensional perspective view representation of buffer transistor 130, according to some embodiments. In the illustrated embodiment, buffer transistor 130 is a two-stage inverter circuit with active region 132A and active region 132B being complementary active regions. In certain embodiments, active region 132A is a p-type active region and active region 132B is an n-type active region.

In various embodiments, buffer transistor 130 utilizes connections to routings 112C-E in metal layer 110 to increase a strength of a signal input to the buffer transistor. In the illustrated embodiment, routing 112D is signal routing, routing 112C is power supply routing, and routing 112E is ground supply routing. Voltage supply input 430 for buffer transistor 130 is provided by connecting routing 112C (e.g., the power supply routing) to source wire 432 (above metal layer 110) using via 434. Source wire 432 then extends over and connects to the source region of active region 132A to provide voltage supply input for buffer transistor 130. Ground supply input 440 for buffer transistor 130 is provided by connecting routing 112E (e.g., the ground supply routing) to source wire 442 (above metal layer 110) using via 444. Source wire 442 then extends over and connects to the source region of active region 132B to provide ground supply input for buffer transistor 130. The power supply routing (e.g., routing 112C) and the ground supply routing (e.g., routing 112E) may also provide electrical shielding for buffer transistor 130 since the routings (e.g., the rails) are positioned along the outer perimeter of the buffer transistor.

In certain embodiments, routing 112D includes input routing 112D′ connected to signal input 410 of buffer transistor 130 and output routing 112D″ connected to signal output 420 of the buffer transistor. Input routing 112D′ and output routing 112D″ may be portions of routing 112D that are physically separated (e.g., cut) in the area of buffer transistor 130. Embodiments may be contemplated where input routing 112D′ and output routing 112D″ are created by insertion of electrical isolation in routing 112D.

In certain embodiments, signal input 410 to buffer transistor 130 is made by connecting input routing 112D′ to gate wire 412 (above metal layer 110) using via 414. Gate wire 412 then extends over both active region 132A and active region 132B to form gates for the first stage of buffer transistor 130 (e.g., the first stage of the two-stage inverter circuit). Gate wire 412 may, for example, extend over the channel regions in both active region 132A and active region 132B. Gate wire 412 may be connected to the channel regions in both active region 132A and active region 132B to provide the input for the first stage.

Output from the first stage is provided through stage output wire 416, which extends over and connects to the drain regions of both active region 132A and active region 132B. In order to route the output of the first stage on stage output wire 416 to an input of the second stage of buffer transistor 130, local interconnect wire 418 may be connected to stage output wire 416. In various embodiments, local interconnect wire 418 may be a c-shaped wire that connects to the ends of stage output wire 416 and then routes over and connects to the channel regions of both active region 132A and active region 132B to provide input for the second stage of buffer transistor 130. Thus, local interconnect wire 418 provides a same layer connection for routing the signal from the output of the first stage to the input of the second stage of buffer transistor 130.

In various embodiments, local interconnect wire 418 is allowed to have its routing if there is sufficient space between metal layer 110 and metal layer 120. For instance, in higher metal layers (e.g., metal layers further away from the transistor region), the metal layers and dielectric among them may be larger and thus have more space for accommodating local interconnect wire 418. Accommodating local interconnect wire 418 may include allow routing of the local interconnect wire without having the local interconnect wire electrically interfere with other wiring or components or without having the local interconnect wire violate any design rules or guidelines. In lower metal layers (e.g., metal layers closer to the transistor region), the height of local interconnect wire 418 may have to be constrained. In some embodiments, local interconnect wire 418 may be formed by using portions of a metal layer above buffer transistor 130 (e.g., portions of metal layer 120). For example, a via may be added to connect stage output wire 416 to local interconnect wire 418 positioned in metal layer 120 above buffer transistor 130.

After local interconnect wire 418 routes the signal to the input of the second stage of buffer circuit 130, the output of the second stage (e.g., the final signal output stage) is provided by stage output wire 422. Stage output wire 422 may be positioned over and connect to the drain regions of both active region 132A and active region 132B. Stage output wire 422 (above metal layer 110) is then connected to routing 112D″ using via 424 to provide signal output 420 for buffer transistor 130. The output signal on signal output 420 has an increased strength over the input signal on signal input 410 after passing through the two-stage inverter circuit of buffer transistor 130 described above.

FIG. 5 depicts a schematic view representation of buffer transistor 130, according to some embodiments. In the illustrated embodiment, buffer transistor 130 includes first stage inverter 510 and second stage inverter 520. In various embodiments, routing 112C carries VDD 506 (e.g., the voltage supply input). Routing 112C is connected to the sources of the p-type region (e.g., active region 132A) in first stage inverter 510 and second stage inverter 520 by source wire 432. Routing 112E carries VSS 508 (e.g., the ground supply input) and is connected to the sources of the n-type region (e.g., active region 132B) in first stage inverter 510 and second stage inverter 520 by source wire 442. These connections to VDD 506 and VSS 508 provide operating power for first stage inverter 510 and second stage inverter 520.

In certain embodiments, first stage inverter 510 receives input signal 502 that is provided on routing 112D′. The output of first stage inverter 510 is then connected to the input of second stage inverter 520 by the combination of stage output wire 416 and local interconnect wire 418. Output signal 504 is then output from second stage inverter 520 on routing 112D″.

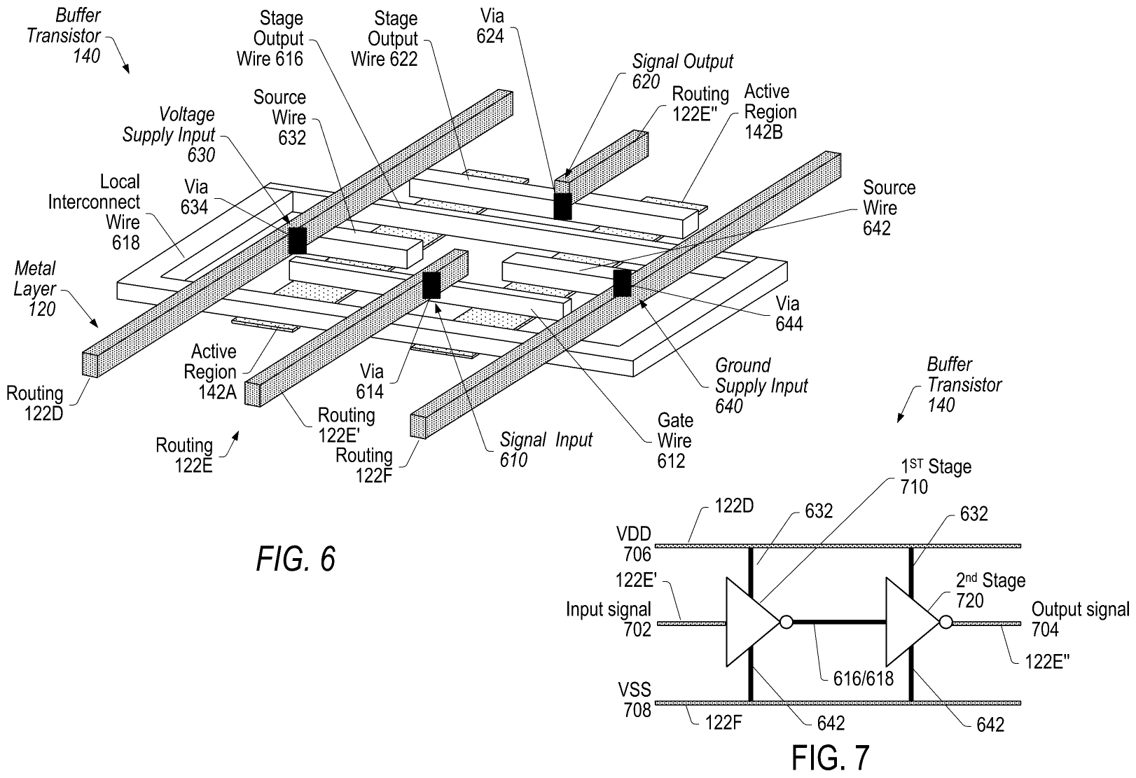

FIG. 6 depicts a three-dimensional perspective view representation of buffer transistor 140, according to some embodiments. In the illustrated embodiment, buffer transistor 140 is a two-stage inverter circuit with active region 132A and active region 132B being complementary active regions. In certain embodiments, active region 142A is a p-type active region and active region 142B is an n-type active region.

In various embodiments, buffer transistor 140 is similar to buffer transistor 130 in structure with connections being made to metal layer 120 instead of metal layer 110. For instance, buffer transistor 140 may utilize connections to routings 122D-F in metal layer 120 to increase a strength of a signal input to the buffer transistor. In the illustrated embodiment, routing 122D power supply routing and routing 122F is ground supply routing. Voltage supply input 630 for buffer transistor 140 is provided by connecting routing 122D (e.g., the power supply routing) to source wire 632 (below metal layer 120) using via 634. Source wire 632 then extends over and connects to the source region of active region 142A to provide voltage supply input for buffer transistor 140. Ground supply input 640 for buffer transistor 140 is provided by connecting routing 122F (e.g., the ground supply routing) to source wire 642 (below metal layer 120) using via 644. Source wire 642 then extends over and connects to the source region of active region 142B to provide ground supply input for buffer transistor 140. The power supply routing (e.g., routing 122D) and the ground supply routing (e.g., routing 122F) may also provide electrical shielding for buffer transistor 140 since the routings (e.g., the rails) are positioned along the outer perimeter of the buffer transistor.

In certain embodiments, routing 122E is the signal routing. Routing 122E may include input routing 122E′ connected to signal input 610 of buffer transistor 140 and output routing 122E″ connected to signal output 620 of the buffer transistor. Input routing 122E′ and output routing 122E″ may be portions of routing 122E that are physically separated (e.g., cut) in the area of buffer transistor 140. Embodiments may be contemplated where input routing 122E′ and output routing 122E″ are created by insertion of electrical isolation in routing 122E.

In certain embodiments, signal input 610 to buffer transistor 140 is made by connecting input routing 122E′ to gate wire 612 (below metal layer 120) using via 614. Gate wire 612 extends over both the channel regions of active region 142A and active region 142B to form gates for the first stage of buffer transistor 140 (e.g., the first stage of the two-stage inverter circuit). Gate wire 612 may be connected to the channel regions in both active region 142A and active region 142B to provide the input for the first stage of buffer transistor 140.

Output from the first stage is provided through stage output wire 616, which extends over and connects to the drain regions of both active region 142A and active region 142B. The output of the first stage on stage output wire 616 is routed to an input of the second stage of buffer transistor 140 by connecting local interconnect wire 618 to stage output wire 616. In various embodiments, local interconnect wire 618 may be a c-shaped wire that connects to the ends of stage output wire 616 and then routes over and connects to the channel regions of both active region 142A and active region 142B to provide input for the second stage of buffer transistor 140. Thus, local interconnect wire 618 may provide a same layer connection for routing the signal from the output of the first stage to the input of the second stage of buffer transistor 140.

In various embodiments, local interconnect wire 618, similar to local interconnect wire 418, is allowed to have its routing if there is sufficient space between metal layer 110 and metal layer 120. Further, accommodating local interconnect wire 618 may include allow routing of the local interconnect wire without having the local interconnect wire electrically interfere with other wiring or components or without having the local interconnect wire violate any design rules or guidelines. In lower metal layers (e.g., metal layers closer to the transistor region), the height of local interconnect wire 618 may have to be constrained. With the constraint, in some embodiments, local interconnect wire 618 may be formed by using portions of a metal layer below buffer transistor 140 (e.g., portions of metal layer 110). For example, a via may be added to connect stage output wire 616 to local interconnect wire 618 positioned in metal layer 110 below buffer transistor 140.

After local interconnect wire 618 routes the signal to the input of the second stage of buffer circuit 140, the output of the second stage (e.g., the final signal output stage) is provided by stage output wire 622. Stage output wire 622 may be positioned over and connect to the drain regions of both active region 142A and active region 142B. Stage output wire 622 (below metal layer 120) connects to routing 122E″ using via 624 to provide signal output 620 for buffer transistor 140. The output signal on signal output 620 has an increased strength over the input signal on signal input 610 after passing through the two-stage inverter circuit of buffer transistor 140 described herein.

FIG. 7 depicts a schematic view representation of buffer transistor 140, according to some embodiments. In the illustrated embodiment, buffer transistor 140 includes first stage inverter 710 and second stage inverter 720. In various embodiments, routing 122D carries VDD 706 (e.g., the voltage supply input). Routing 122D is connected to the sources of the p-type region (e.g., active region 142A) in first stage inverter 710 and second stage inverter 720 by source wire 632. Routing 122F carries VSS 708 (e.g., the ground supply input) and is connected to the sources of the n-type region (e.g., active region 142B) in first stage inverter 710 and second stage inverter 720 by source wire 642. These connections to VDD 706 and VSS 708 provide operating power for first stage inverter 710 and second stage inverter 720.

In certain embodiments, first stage inverter 710 receives input signal 702 that is provided on routing 122E′. The output of first stage inverter 710 is then connected to the input of second stage inverter 720 by the combination of stage output wire 616 and local interconnect wire 618. Output signal 704 is then output from second stage inverter 720 on routing 122E″. As described above, both buffer transistor 130 and buffer transistor 140 are two-stage inverter circuits that are capable of providing output signals (e.g., output signal 504 and output signal 704) that are increased in strength over input signals (e.g., input signal 502 and input signal 702). With the buffer transistors being positioned between two metal layers (e.g., metal layer 110 and metal layer 120, as shown in FIGS. 2 and 3), the buffer transistors are able to provide this buffering (e.g., amplification) of signals propagating through device 100 without any growth in footprint or area of the device as the buffer transistors are being positioned in already existing space in the device.

The number and layout (e.g., placement) of the buffer transistors described herein (e.g., buffer transistor 130 or buffer transistor 140) may be varied based on the design or operational needs of a device implementing the buffer transistors. For example, embodiments may be contemplated where multiple buffer transistors are stacked together across multiple columns or rows of routing in a device (e.g., across multiple routings in metal layer 110 or metal layer 120). In some embodiments, buffer transistors that are stacked together may share a common ground supply routing between them. In such embodiments, the stacked buffer transistors may be stacked in alignment (e.g., if width of active regions is constrained) or stacked in a staggered pattern to allow larger active region widths.

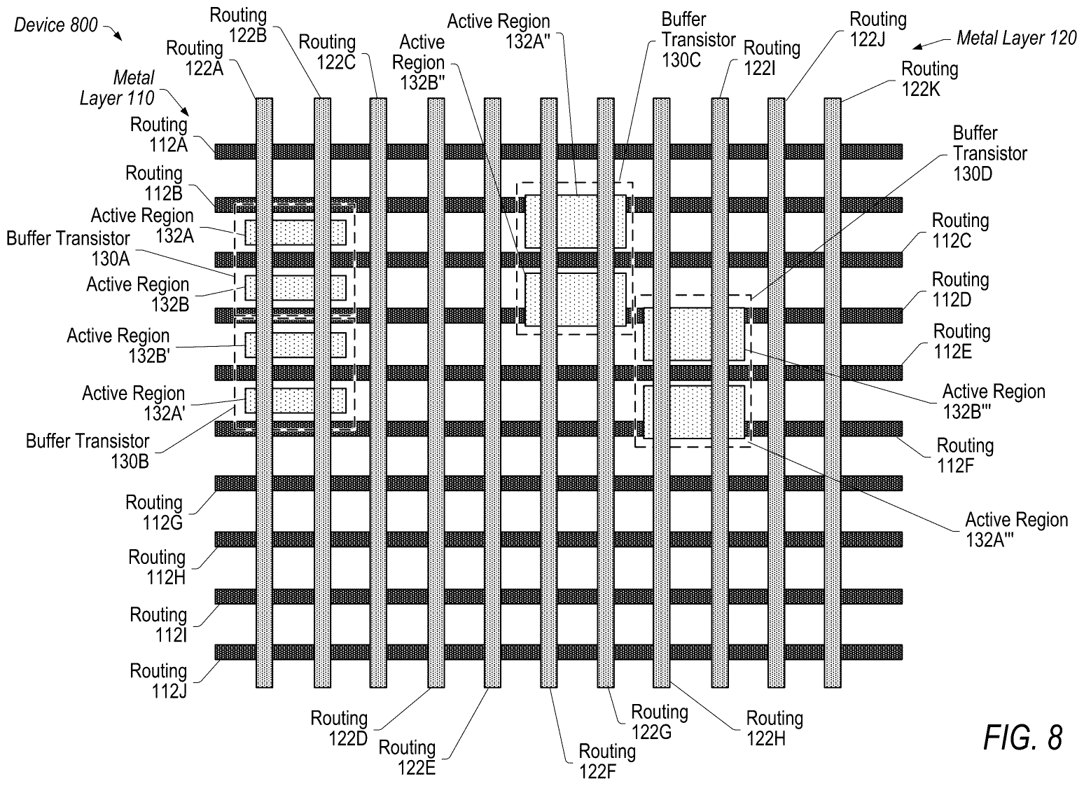

FIG. 8 depicts a topside plan view representation of a contemplated device showing various layouts of buffer transistors, according to some embodiments. In the illustrated embodiment, device 800 includes metal layer 110 with routings 112A-112J and metal layer 120 with routings 122A-122K. Routings 112B and 112F may be power supply routings (e.g., VDD) while routing 112D is ground supply routing. Routings 112C and 112E may be signal routings.

The pairing of buffer transistor 130A (with active region 132A and active region 132B) and buffer transistor 130B (with active region 132A′ and active region 132B′) represents a pair of buffer transistors stacked in alignment. Note that the complementary pairs of active regions are flipped between buffer transistor 130A and buffer transistor 130B to allow the buffer transistors to share the ground supply routing—routing 112D. Thus, active region 132B of buffer transistor 130A is adjacent active region 132B′ of buffer transistor 130B. While buffer transistor 130A and buffer transistor 130B share a common ground supply routing, the buffer transistors have separate power supply routings (e.g., routing 112B and routing 112F, respectively) and also operate to buffer (e.g., amplify) different signals on different signal routings (e.g., routing 112C and routing 112E, respectively).

As buffer transistor 130A and buffer transistor 130B are aligned (e.g., the left and right edges of the buffer transistors are aligned in the illustration), the widths of active regions 132 are constrained and not allowed to be increased (note that the widths of the active regions are vertical in the illustration). Staggering the buffer transistors, as shown by buffer transistor 130C and buffer transistor 130D in FIG. 8, may allow the widths of active regions 132 to be increased. In the illustrated embodiment, buffer transistor 130C includes active region 132A″ and active region 132B″ while buffer transistor 130D includes active region 13A′″ and active region 132B′″.

As with the pairing of buffer transistor 130A and buffer transistor 130B, the complementary pairs of active regions are flipped between buffer transistor 130C and buffer transistor 130D to allow the ground supply routing—routing 112D—to be shared by the buffer transistors. With the staggering of buffer transistor 130C and buffer transistor 130D, however, the widths of active region 132A″, active region 132B″, active region 13A′″, and active region 132B′″ may be increased since there is no constraint on the size from a neighboring buffer transistor. For instance, the size of active region 132A″ and active region 132B″ in buffer transistor 130C is not constrained by the placement of buffer transistor 130D and vice versa. Accordingly, the staggering of buffer transistor 130C and buffer transistor 130D enables wider active regions to be implemented in device 800. These wider active regions may be utilized to increase amplification strength of the buffer transistors. For example, the signal strength increase provided by buffer transistors 130C/130D may be larger than the signal strength increase provided by buffer transistors 130A/130B. With the active regions rotated by 90 degrees in a horizontal dimension parallel to the substrate, stacked buffer transistors may be stacked in alignment (e.g., if width of active regions is constrained) or stacked in a staggered pattern using metal layer 120 as routing (for example, 122A-122K), as well.

Although buffer transistors are described above, it is logical and easy for those of ordinary skill in the art to construct other logic functions and logic gates using the described concept and construct. For example, inverters can be constructed by only adopting the second stage in buffers. And for another example, other logic gates (such as NAND and NOR) can be constructed by using more routing metal tracks in either metal layer 110 or metal layer 120 with the freedom to adjust the sizes and widths of the active regions.

### Example Computer System

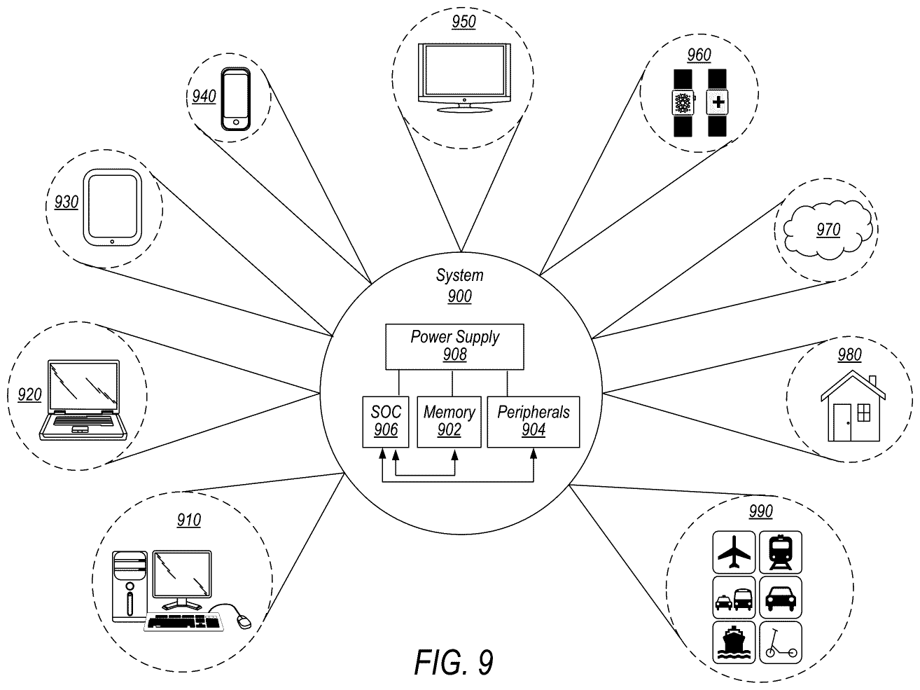

Turning next to FIG. 9, a block diagram of one embodiment of a system 900 is shown that may incorporate and/or otherwise utilize the methods and mechanisms described herein. In the illustrated embodiment, the system 900 includes at least one instance of a system on chip (SoC) 906 which may include multiple types of processing units, such as a central processing unit (CPU), a graphics processing unit (GPU), or otherwise, a communication fabric, and interfaces to memories and input/output devices. In some embodiments, one or more processors in SoC 906 includes multiple execution lanes and an instruction issue queue. In various embodiments, SoC 906 is coupled to external memory 902, peripherals 904, and power supply 908.

A power supply 908 is also provided which supplies the supply voltages to SoC 906 as well as one or more supply voltages to the memory 902 and/or the peripherals 904. In various embodiments, power supply 908 represents a battery (e.g., a rechargeable battery in a smart phone, laptop or tablet computer, or other device). In some embodiments, more than one instance of SoC 906 is included (and more than one external memory 902 is included as well).

The memory 902 is any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices are coupled onto a circuit board to form memory modules such as single inline memory modules (SIMMs), dual inline memory modules (DIMMs), etc. Alternatively, the devices are mounted with a SoC or an integrated circuit in a chip-on-chip configuration, a package-on-package configuration, or a multi-chip module configuration.

The peripherals 904 include any desired circuitry, depending on the type of system 900. For example, in one embodiment, peripherals 904 includes devices for various types of wireless communication, such as Wi-Fi, Bluetooth, cellular, global positioning system, etc. In some embodiments, the peripherals 904 also include additional storage, including RAM storage, solid state storage, or disk storage. The peripherals 904 include user interface devices such as a display screen, including touch display screens or multitouch display screens, keyboard or other input devices, microphones, speakers, etc.

As illustrated, system 900 is shown to have application in a wide range of areas. For example, system 900 may be utilized as part of the chips, circuitry, components, etc., of a desktop computer 910, laptop computer 920, tablet computer 930, cellular or mobile phone 940, or television 950 (or set-top box coupled to a television). Also illustrated is a smartwatch and health monitoring device 960. In some embodiments, smartwatch may include a variety of general-purpose computing related functions. For example, smartwatch may provide access to email, cellphone service, a user calendar, and so on. In various embodiments, a health monitoring device may be a dedicated medical device or otherwise include dedicated health related functionality. For example, a health monitoring device may monitor a user's vital signs, track proximity of a user to other users for the purpose of epidemiological social distancing, contact tracing, provide communication to an emergency service in the event of a health crisis, and so on. In various embodiments, the above-mentioned smartwatch may or may not include some or any health monitoring related functions. Other wearable devices are contemplated as well, such as devices worn around the neck, devices that are implantable in the human body, glasses designed to provide an augmented and/or virtual reality experience, and so on.

System 900 may further be used as part of a cloud-based service(s) 970. For example, the previously mentioned devices, and/or other devices, may access computing resources in the cloud (i.e., remotely located hardware and/or software resources). Still further, system 900 may be utilized in one or more devices of a home 980 other than those previously mentioned. For example, appliances within the home may monitor and detect conditions that warrant attention. For example, various devices within the home (e.g., a refrigerator, a cooling system, etc.) may monitor the status of the device and provide an alert to the homeowner (or, for example, a repair facility) should a particular event be detected. Alternatively, a thermostat may monitor the temperature in the home and may automate adjustments to a heating/cooling system based on a history of responses to various conditions by the homeowner. Also illustrated in FIG. 9 is the application of system 900 to various modes of transportation 990. For example, system 900 may be used in the control and/or entertainment systems of aircraft, trains, buses, cars for hire, private automobiles, waterborne vessels from private boats to cruise liners, scooters (for rent or owned), and so on. In various cases, system 900 may be used to provide automated guidance (e.g., self-driving vehicles), general systems control, and otherwise. These any many other embodiments are possible and are contemplated. It is noted that the devices and applications illustrated in FIG. 9 are illustrative only and are not intended to be limiting. Other devices are possible and are contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by “a,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, circuit, a system having a processor unit and a memory storing program instructions executable to implement the task, etc. This phrase is not used herein to refer to something intangible.

In some cases, various units/circuits/components may be described herein as performing a set of task or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements defined by the functions or operations that they are configured to implement, The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. An apparatus, comprising:
a transistor region of an integrated circuit, the transistor region being above a substrate in a vertical dimension perpendicular to the substrate;
a first metal layer located above the transistor region in the vertical dimension;
a second metal layer located above first metal layer in the vertical dimension;
wherein at least one of the first metal layer and the second metal layer includes power supply routing, ground supply routing, and signal routing; and
a transistor circuit positioned between the first metal layer and the second metal layer in the vertical dimension, wherein the transistor circuit includes:
an active region;
a gate;
a signal input coupled to the gate and a portion of the signal routing;
a voltage supply input for the active region coupled to the power supply routing;
a ground supply input for the active region coupled to the ground supply routing; and
a signal output coupled to an additional portion of the signal routing.

2. The apparatus of claim 1, wherein the transistor circuit is a buffer transistor circuit configured to increase a strength of a signal received at the signal input.

3. The apparatus of claim 1, wherein the transistor circuit is an inverter transistor circuit, the active region including a p-type active region and an n-type active region.

4. The apparatus of claim 3, wherein the transistor circuit further includes local vias between one or more of the gate, the voltage supply input, the ground supply input, and the signal output and one or both of the first and second metal layers.

5. The apparatus of claim 3, wherein the transistor circuit further includes a local interconnect wire between drain regions and gate regions of the active region.

6. The apparatus of claim 1, wherein the power supply routing, the ground supply routing, and the signal routing are oriented in parallel in a horizontal dimension parallel to the substrate, and wherein the active region is positioned between the power routing and the ground routing in the horizontal dimension.

7. The apparatus of claim 1, further comprising an additional transistor circuit positioned between the first metal layer and the second metal layer in the vertical dimension, wherein the additional transistor circuit includes an additional active region.

8. The apparatus of claim 7, wherein the additional active region is oriented orthogonally to the active region in a horizontal dimension parallel to the substrate.

9. The apparatus of claim 1, wherein the transistor circuit is positioned in a dielectric layer between the first metal layer and the second metal layer.

10. The apparatus of claim 1, wherein the active region is formed by a thin channel material positioned in between the first metal layer and the second metal layer.

11. An apparatus, comprising:
a transistor circuit positioned within a transistor region of an integrated circuit, the transistor being above a substrate in a vertical dimension perpendicular to the substrate;
a first metal layer located above the transistor region in the vertical dimension;
a second metal layer located above the transistor region in the vertical dimension;
wherein at least one of the first metal layer and the second metal layer includes power supply routing, ground supply routing, and signal routing, wherein a portion of the signal routing is coupled to the transistor circuit; and
a transistor circuit positioned between the first metal layer and the second metal layer in the vertical dimension, wherein the transistor circuit includes:
a p-type active region;
an n-type active region;
a gate input coupled to the portion of the signal routing that is coupled to the transistor circuit;
a voltage supply input coupled to a source region in the p-type active region and the power supply routing;
a ground supply input coupled to a source region in the n-type active region and the ground supply routing; and
a gate output coupled to an additional portion of the signal routing.

12. The apparatus of claim 11, wherein the power supply routing, the ground supply routing, and the signal routing are oriented in parallel along a first direction in a horizontal dimension parallel to the substrate.

13. The apparatus of claim 12, wherein the p-type active region and the n-type active region are oriented in parallel along the first direction in the horizontal dimension.

14. The apparatus of claim 12, wherein the transistor circuit includes a gate wire oriented along a second direction in the horizontal dimension, the second direction being perpendicular to the first direction, and wherein the gate wire extends over both the p-type active region and the n-type active region in the vertical dimension.

15. The apparatus of claim 11, wherein the voltage supply input includes:
a metal wire positioned at least partially above the source region in the p-type active region; and
a via coupled between the metal wire and the power supply routing.

16. The apparatus of claim 11, wherein the ground supply input includes:
a metal wire positioned at least partially above the source region in the n-type active region; and
a via coupled between the metal wire and the ground supply routing.

17. The apparatus of claim 11, wherein the transistor circuit includes:
a first gate wire oriented along a direction in a horizontal dimension, wherein the gate wire is positioned at least partially above channel regions of both the p-type active region and the n-type active region in the vertical dimension;
a first stage output wire oriented along the direction, wherein the first stage output wire is positioned at least partially above drain regions of both the p-type active region and the n-type active region in the vertical dimension; and
a local interconnect wire connected to both ends of the first stage output wire, wherein at least a portion of the local interconnect wire is positioned above the channel regions of both the p-type active region and the n-type active region in the vertical dimension.

18. The apparatus of claim 17, wherein the gate output includes a second stage output wire oriented along the second direction, wherein the second stage output wire is positioned at least partially above the drain regions of both the p-type active region and the n-type active region in the vertical dimension.

19. The apparatus of claim 11, wherein the transistor circuit is positioned in a dielectric layer between the first metal layer and the second metal layer.

20. An apparatus, comprising:
a transistor region of an integrated circuit, the transistor region being above a substrate in a vertical dimension perpendicular to the substrate;
a first metal layer located above the transistor region in the vertical dimension, wherein the first metal layer includes first power supply routing, first ground supply routing, and first signal routing;
a second metal layer located above the first metal layer in the vertical dimension, wherein the second metal layer includes second power supply routing, second ground supply routing, and second signal routing; and
a first buffer transistor circuit positioned between the first metal layer and the second metal layer in the vertical dimension, wherein the first buffer transistor circuit includes:
a first p-type active region;
a first n-type active region;
a first gate input coupled to a portion of the first signal routing;
a first voltage supply input coupled to a first source region in the first p-type active region and the first power supply routing;
a first ground supply input coupled to a first source region in the first n-type active region and the first ground supply routing; and
a first gate output coupled to an additional portion of the first signal routing; and
a second buffer transistor circuit positioned between the first metal layer and the second metal layer in the vertical dimension, wherein the second buffer transistor circuit includes:
a second p-type active region;
a second n-type active region;
a second gate input coupled to a portion of the second signal routing;
a second voltage supply input coupled to a second source region in the second p-type active region and the second power supply routing;
a second ground supply input coupled to a second source region in the second n-type active region and the second ground supply routing; and
a second gate output coupled to an additional portion of the second signal routing.
